(19) United States
(12) Patent Application Publication
(10) Pub. No.: US 2016/0362778 A1
(43) Pub. Date: Dec. 15, 2016

(54) Vacuum Evaporation Apparatus

(71) Applicants: BOE Technology Group Co., Ltd., Beijing (CN); Hefei Xinsheng Optoelectronics Technology Co., Ltd., Anhui (CN)

(72) Inventors: Xiyuan Wang, Beijing (CN); Bin Bu, Beijing (CN); Gu Yao, Beijing (CN)

(21) Appl. No.: 15/153,346

(22) Filed: May 12, 2016

(30) Foreign Application Priority Data
Jun. 11, 2015 (CN) 201510325726.7

(51) Int. Cl. C23C 14/24

(52) U.S. Cl. CPC C23C 14/243

(57) ABSTRACT

A vacuum evaporation apparatus comprises a housing, in which a main vacuum cavity, a side vacuum cavity and a switch assembly are disposed. The main vacuum cavity is configured for vacuum evaporation. A tomography detection module for scanning a crucible to be measured and a manipulator for accessing a crucible in main vacuum cavity are disposed in the side vacuum cavity. A switch assembly is disposed between the main vacuum cavity and the side vacuum cavity. Where the switch assembly is opened, the main vacuum cavity and the side vacuum cavity are communicated with each other to enable accessing the crucible. Where the switch assembly is closed, the main vacuum cavity and the side vacuum cavity are separated from each other.

This application claims priority to and the benefit of Chinese Patent Application No. 201510325726.7 filed on Jun. 11, 2015, which application is incorporated herein in its entirety.

### TECHNICAL FIELD

Embodiments of the present disclosure relate to a vacuum evaporation apparatus.

### BACKGROUND

At present, in the preparation process of bottom-emitting-type OLED, it is required to prepare a metallic cathode in a vacuum evaporation apparatus. In the vacuum evaporation apparatus, metallic material to be evaporated which is used to prepare the metallic cathode of the OLED, typically aluminum, is held in a crucible.

In the process of forming the metallic cathode of the OLED by vacuum evaporation, melted aluminum has a property of immersing the crucible, so that the melted aluminum tends to creep along the wall of the crucible in the evaporation process and thus spill over the crucible. When the temperature is lowered, solidified aluminum is inclined to have the crucible stuck to surrounding objects and thus damaged. And, the process temperature in the environment of the evaporation process where the crucible is placed amounts to 1100° C. to 1200° C. Micro cracks are prone to occur to the crucible due to thermal shock during rise and drop of temperature. If the crucible continues to be used, the micro cracks will be developed, and the crucible will have macro cracks and thus tend to crack.

However, due to immersing and “creeping” properties of aluminum material, an idle running operation is required after each evaporation is finished so that aluminum remained in the crucible is completely evaporated and then the temperature is allowed to be lowered. After the idle running operation of the crucible, to ensure that there is no cracks in the crucible, the vacuum cavity is usually opened before refilling material and the crucible is taken out and subject to visual inspection, which will make the crucible frequently switched between high temperature state and low temperature state and thus increase a risk of micro cracks presenting on the crucible. In addition, in the above method of determining whether there is a micro crack in the crucible, the visual inspection has low accuracy and high error probability which leads to great safety margin of an estimated life of the crucible and thus the crucible serves for a short time in practical production, the preparation time for production and thus the production cost is increased.

### SUMMARY

At least one embodiment of the present disclosure provides a vacuum evaporation apparatus. The vacuum evaporation apparatus comprises a device for on-line detecting and replacing a crucible. By tomography scanning technology, sizes and positions of micro cracks inside the crucible as well as on the surface of the crucible can be precisely detected so that a damaged crucible is on-line replaced with a new one in a vacuum environment.

A vacuum evaporation apparatus comprises a housing in which a main vacuum cavity, a side vacuum cavity and a switch assembly are disposed. A manipulator configured to access a crucible within the main vacuum cavity and a tomography detecting module configured to detect a crucible under test are disposed in the side vacuum cavity. The switch assembly is disposed between the main vacuum cavity and the side vacuum cavity. When the switch assembly is opened, the main vacuum cavity and the side vacuum cavity are communicated with each other. When the switch assembly is closed, the main vacuum cavity and the side vacuum cavity are separated from each other.

In the above vacuum evaporation apparatus, when the crucible within the main vacuum cavity is to be detected after completing an evaporation operation, the side vacuum cavity is firstly evacuated and the switch assembly is opened when the vacuum degree within the side vacuum cavity is close to that of the main vacuum cavity. The manipulator is extended from the side vacuum cavity into the main vacuum cavity to fetch the crucible and puts it into the side vacuum cavity. The tomography detecting module detects sizes and positions of micro cracks inside the crucible as well as on the surface of the crucible. The above vacuum evaporation apparatus can perform an on-line detection on the crucible without destroying the vacuum degree within the vacuum evaporation apparatus so as to not affect the normal production procedure of the vacuum evaporation apparatus, and can detect the crucible by the tomography detection module to determine whether there is a micro crack in the crucible under test and the detection has a high accuracy. And, the above vacuum evaporation apparatus can perform the detection on the crucible within the main vacuum cavity without destroying the vacuum environment within the main vacuum cavity, thereby making the service life of each crucible to be maximum, prolonging time interval to replace the crucible in practical production, reducing preparation time for production and thus decreasing production cost.

### BRIEF DESCRIPTION OF THE DRAWINGS

In order to clearly illustrate the technical solutions of the embodiments of the disclosure, the drawings of the embodiments will be briefly described in the following; it is obvious that the drawings described below are only related to some embodiments of the disclosure and thus are not limitative of the disclosure.

FIG. 1 is an illustrative structural view of the vacuum evaporation apparatus according to the present disclosure.

### DETAILED DESCRIPTION

In order to make objects, technical details and advantages of the embodiments of the disclosure apparent, the technical solutions of the embodiment will be described in a clearly and fully understandable way in connection with the drawings related to the embodiments of the disclosure. It is obvious that the described embodiments are just a part but not all of the embodiments of the disclosure. Based on the described embodiments herein, those skilled in the art can obtain other embodiment(s), without any inventive work, which should be within the scope of the disclosure.

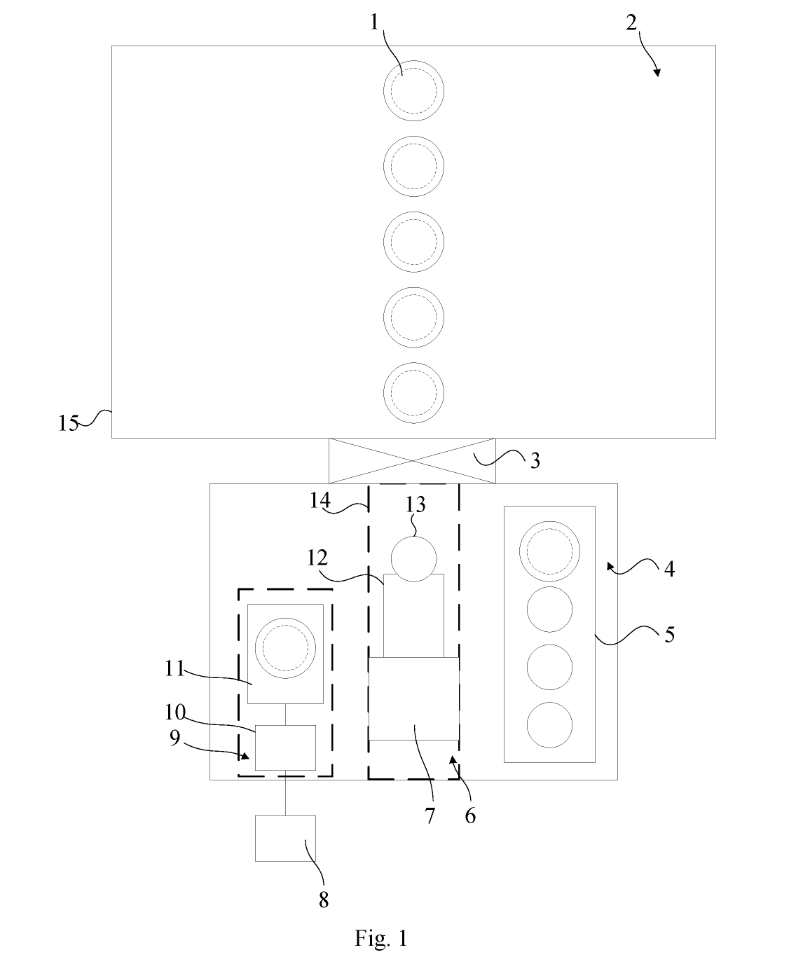

As illustrated in FIG. 1, the vacuum evaporation apparatus according to the embodiment of the present disclosure comprises a housing 15 in which a main vacuum cavity 2, a side vacuum cavity 4 and a switch assembly 3 are disposed. A manipulator 6 configured to put the crucible into the main vacuum cavity or take the crucible out of the main vacuum cavity and a tomography detecting module 9 configured to detect the crucible 1 under test are disposed in the side vacuum cavity 4. The switch assembly 3 is disposed between the main vacuum cavity 2 and the side vacuum cavity 4. The main vacuum cavity 2 and the side vacuum cavity 4 are communicated with each other when the switch assembly 3 is opened and are separated from each other when the switch assembly 3 is closed.

In the above vacuum evaporation apparatus, when the crucible 1 within the main vacuum cavity 2 is to be detected after an evaporation operation is completed, the side vacuum cavity 4 is firstly evacuated and the switch assembly 3 is opened when the vacuum degree within the side vacuum cavity 4 is close to that of the main vacuum cavity 2. The manipulator 6 is extended from the side vacuum cavity 4 into the main vacuum cavity 2 to take out the crucible 1 and puts it into the side vacuum cavity 4. The tomography detecting module 9 detects sizes and positions of the micro cracks inside the crucible 1 as well as on the surface of the crucible 1. The above vacuum evaporation apparatus can perform an on-line detection on the crucible 1 without destroying the vacuum degree within the main vacuum cavity 2 so as to not affect the normal production procedure, and can scan the crucible 1 by the tomography detecting module 9 so that the detection accuracy of the crucible 1 is high. And, the above vacuum evaporation apparatus can perform the detection on the crucible 1 within the main vacuum cavity 4 without destroying the vacuum environment within the main vacuum cavity 4, thereby making the service life of each crucible 1 to be maximum, prolonging time interval to replace the crucible 1 in practical production, reducing preparation time for production and thus decreasing production cost.

Referring to FIG. 1, in one embodiment according to the present disclosure, the switch assembly 3 is a vacuum plug valve having advantages of large flow conductance, good sealing performance, low outgassing rate, small volume, compact and reasonable structure, convenient operation and optional installation position and etc.

Still referring to FIG. 1, in one embodiment according to the present disclosure, the tomography detecting module 9 comprises:

a scanning unit 11 which is configured to scan the sampling crucible 1 and generate a scanning information; and

a processing unit 10 which is configured to connect by signal with the scanning unit 11, receive the scanning information and determine whether there is a micro crack in the crucible on the basis of the scanning information.

In one embodiment according to the present disclosure, the above-described scanning unit 11 is an X-ray scanning device.

The processing unit 10 is configured to convert the received scanning information into image information. The vacuum evaporation apparatus further comprises a display unit 8 which is configured to connect by signal with the processing unit 10 so as to receive and display the image information.

The tomography scanning technology adopts X-ray to scan a certain thickness of a sample layer by layer. After the X-ray which is transmitted through the layer and received by a detector is converted into visible light, the visible light is converted into an electrical signal by a photoelectric convertor and then is converted into a digital signal through analog-to-digital conversion. The digital signal is processed to form an image information. Substance has a property of absorbing X-ray. Attenuation of X-ray in a homogeneous object complies with the exponential law. Since the sample is constituted by various substances with different components and densities, there are differences in absorption coefficients of X-ray at respective points which can be amplified and reflected on the image signal.

The crucible 1 is scanned by X-ray and the X-ray signal transmitted through the crucible 1 is collected as scanning information. The scanning information is processed and a CT image of the crucible 1 is produced and is displayed by the display unit 8. It can be seen from the CT image whether there is a micro crack inside the crucible 1 and on the surface of the crucible 1. If there is any micro crack, the size and the position of the micro crack can be precisely determined, thereby making a fast, nondestructive and highly precious measurement.

In one embodiment of the present disclosure, a guide rail 14 is provided in the side vacuum cavity 4. The manipulator 6 is mounted on the guide rail 14.

The manipulator 6 comprises a slider 7, a telescopic arm 12 and a crucible fetching device 13. The slider 7 is in sliding fit with the guide rail 14. The telescopic arm 12 is disposed on the slider. The crucible fetching device 13 is mounted on a distal end of the telescopic arm 12.

In one embodiment according to the present disclosure, the above-described vacuum evaporation apparatus further comprises a crucible rack 5 located in the side vacuum cavity 4.

The crucible rack 5 is configured to store crucibles with micro cracks which are determined to be those that cannot be used anymore and new crucibles, so that it is ensured that a crucible replacing operation is performed under vacuum condition without opening the vacuum cavity when replacing the crucible.

In one embodiment of the present disclosure, the side vacuum cavity 4 and the main vacuum cavity 2 are distributed in series. The tomography detecting module 9 and the manipulator 6 are positioned in the side vacuum cavity 4. By means of the manipulator 6, a damaged crucible can be taken out conveniently and is replaced by a new one on line without opening the vacuum cavity by manual operation.

The slider 7 is moved along the guide rail 14 and the telescopic arm 12 is protruded to grasp a crucible 1 to be measured in the main vacuum cavity 2 by the crucible fetching device 13 at its leading end and put it into the side vacuum cavity. The tomography detecting module 9 scans the crucible 1 and a CT image of the crucible is generated and output. From the image, the sizes and the positions of the micro cracks inside the crucible 1 as well as on the surface of the crucible 1 can be seen. A crucible with micro cracks which is determined to be the one that cannot be used anymore is taken out and placed onto the crucible rack and a new crucible is selected from the rack and put into the main vacuum cavity to perform the replacement. Finally, the slider moves back to the initial position and close the plug valve. It has advantages of fast measuring speed, no damage to the sample, free from contact and high measuring accuracy.

In one embodiment of the present disclosure, a crucible for evaporating other materials such as metallic material and organic EL material is to be detected and replaced. The crucible under test can be made of ceramic materials or metallic materials, can be of one-layer structure or multi-layer structure.

The foregoing are merely exemplary embodiments of the disclosure, but are not used to limit the protection scope of the disclosure. The protection scope of the disclosure shall be defined by the attached claims.

The present disclosure claims priority of Chinese Patent Application No. 201510325726.7 filed on Jun. 11, 2015, the disclosure of which is hereby entirely incorporated by reference as a part of the present disclosure.

1. A vacuum evaporation apparatus, comprising:
a housing, in which a main vacuum cavity, a side vacuum cavity and a switch assembly are disposed, wherein a manipulator which is configured to put a crucible into the main vacuum cavity or take a crucible out of the main vacuum cavity and a tomography detecting module which is configured to detect a crucible under test are disposed in the side vacuum cavity, the main vacuum cavity is configured for evaporation apparatus, the switch assembly is disposed between the main vacuum cavity and the side vacuum cavity, the main vacuum cavity and the side vacuum cavity are communicated with each other where the switch assembly is opened and are separated from each other where the switch assembly is closed.

2. The vacuum evaporation apparatus according to claim 1, wherein the switch assembly is a vacuum plug valve.

3. The vacuum evaporation apparatus according to claim 1, wherein the tomography detecting module comprises:
a scanning unit configured to collect scanning information obtained by scanning micro crack of the crucible; and
a processing unit connected by signal with the scanning unit and configured to determine whether there is a micro crack in the crucible on the basis of the scanning information collected by the scanning unit.

4. The vacuum evaporation apparatus according to claim 3, wherein the scanning unit is an X-ray scanning device.

5. The vacuum evaporation apparatus according to claim 3, wherein the processing unit is configured to convert the scanning information received from the scanning unit into image information.

6. The vacuum evaporation apparatus according to claim 5, further comprising a display unit which is configured to connect by signal with the processing unit and receive and display the image information.

7. The vacuum evaporation apparatus according to claim 1, wherein a guide rail is provided in the side vacuum cavity and the manipulator is mounted on the guide rail.

8. The vacuum evaporation apparatus according to claim 7, wherein the manipulator comprises a slider which is in sliding fit with the guide rail, a telescopic arm which is disposed on the slider and a crucible fetching device which is mounted on a distal end of the telescopic arm.

9. The vacuum evaporation apparatus according to claim 1, further comprising a crucible rack located in the side vacuum cavity.

10. The vacuum evaporation apparatus according to claim 1, wherein the side vacuum cavity and the main vacuum cavity are distributed in series.

11. The vacuum evaporation apparatus according to claim 2, wherein the tomography detecting module comprises:
a scanning unit configured to collect scanning information about micro crack of the crucible; and
a processing unit connected by signal with the scanning unit and configured to determine whether there is a micro crack in the crucible on the basis of the scanning information obtained by the scanning unit.

12. The vacuum evaporation apparatus according to claim 11, wherein the scanning unit is an X-ray scanning device.

13. The vacuum evaporation apparatus according to claim 11, wherein the processing unit is configured to convert the scanning information received from the scanning unit into image information.

14. The vacuum evaporation apparatus according to claim 13, further comprising a display unit which is configured to connect by signal with the processing unit and receive and display the image information.

15. The vacuum evaporation apparatus according to claim 2, wherein a guide rail is provided in the side vacuum cavity and the manipulator is mounted on the guide rail.

16. The vacuum evaporation apparatus according to claim 15, wherein the manipulator comprises a slider which is in sliding fit with the guide rail, a telescopic arm which is disposed on the slider and a crucible fetching device which is mounted on a distal end of the telescopic arm.

17. The vacuum evaporation apparatus according to claim 2, further comprising a crucible rack located in the side vacuum cavity.

18. The vacuum evaporation apparatus according to claim 2, wherein the side vacuum cavity and the main vacuum cavity are distributed in series.

19. The vacuum evaporation apparatus according to claim 6, wherein the manipulator comprises a slider which is in sliding fit with the guide rail, a telescopic arm which is disposed on the slider and a crucible fetching device which is mounted on a distal end of the telescopic arm.

20. The vacuum evaporation apparatus according to claim 19, further comprising a crucible rack located in the side vacuum cavity.
